(19) United States
(12) Patent Application Publication
(10) Pub. No.: US 2009/0130602 A1
(43) Pub. Date: May 21, 2009

(54) METHOD FOR MANUFACTURING IMAGE SENSOR

(76) Inventor: Yeon-Ah Shim, Hampyeong-gun (KR)

Correspondence Address: SHERR & VAUGHN, PLLC, 620 HERNDON PARKWAY, SUITE 200, HERNDON, VA, 20170, US

(21) Appl. No.: 12/271,888

(22) Filed: Nov. 15, 2008

(30) Foreign Application Priority Data
Nov. 19, 2007 (KR) 10-2007-0117701

(51) Int. Cl. G03F 7/20

(52) U.S. Cl. 430/312

(57) ABSTRACT

A method for manufacturing an image sensor that does not include a reflow process but includes exposing a photoresist film a plurality of times from various angles and then forming one or more micro lenses by developing the exposed photoresist film.

The present application claims priority under 35 U.S.C. §119 to Korean Patent Application No. 10-2007-0117701 (filed on November 2007), which is hereby incorporated by reference in its entirety.

### BACKGROUND

An image sensor is a semiconductor device converting an optical image into an electrical signal, and it is largely divided into a charge coupled device (CCD) image sensor and a complementary metal oxide silicon (CMOS) image sensor (CIS). The CIS forms a photodiode and a MOS transistor within a unit pixel to sequentially detect electrical signals of each unit pixel, implementing an image. The CIS has a photodiode region in which light is received to be converted into an electric signal and a transistor region in which the electric signal is progressed. In order to improve photosensitivity, the image sensor may use a technique to enlarge a fill factor occupied by photodiodes from among the entire regions or convert path of light incident on regions other than the photo diodes to be focused on the photodiodes.

The representative example of the focusing technique is to form a micro lens. In order to form a micro lens in a fabricating process of an image sensor, a micro photo process is progressed using a special photoresist film for micro lens and then a reflowing method is used. However, the process of reflowing the special photoresist film for forming the micro lens is complicated and has a problem of causing a bridge or micro lens gap. Also, in order to form the micro lens, the quantity of the photoresist film lost when reflowing the photoresist film increases. As a result, a gap is generated between micro lenses such that the quantity of light incident on the photodiodes is reduced, and in turn, generates image defects. Moreover, when forming the micro lens, the difference in focal length between a horizontal axis and a diagonal axis of the micro lens is generated to cause a crosstalk phenomenon in the pixel.

### SUMMARY

Embodiments relate to a method for fabricating a semiconductor device such as an image sensor.

Embodiments relate to a method for manufacturing an image sensor which can form a micro lens without a reflowing process.

Embodiments relate to a method for manufacturing an image sensor which can prevent bridge formation between micro lenses and also minimize the gap between the micro lenses.

Embodiments relate to a method for manufacturing an image sensor that may include at least one of the following: forming an interlayer dielectric layer on and/or over a substrate in which a photodiode is formed; forming a photoresist film on and/or over the interlayer dielectric layer; exposing the photoresist film a plurality of times from a plurality of angles; and forming a micro lens by developing the exposed photoresist film.

Embodiments relate to a method that may include at least one of the following: forming an interlayer dielectric layer over a substrate in which a photodiode is formed; and then forming a photoresist film over the interlayer dielectric layer; and then exposing the photoresist film a plurality of times from a plurality of different angles; and then forming a micro lens by developing the exposed photoresist film.

Embodiments relate to a method that may include at least one of the following: providing a substrate having a plurality of photodiodes formed therein; and then forming a dielectric layer over the substrate including the photodiodes; and then forming a color filter layer over the dielectric layer; and then forming a planarization layer over the color filter layer; and then forming a photoresist film over the planarization layer; and then performing a first focusing process on the photoresist film; and then performing a second focusing process on the photoresist film after using a performing the first focusing process; and then forming a micro lens by developing the photoresist film after performing the second focusing process.

Embodiments relate to a method that may include at least one of the following: forming a color filter layer over a substrate having a plurality of photodiodes formed therein; and then forming a photoresist film over the color filter layer; and then sequentially performing first and second exposure processes on the photoresist film; and then forming a micro lens by developing the photoresist film after performing the second exposure process.

Embodiments relate to a method that may include at least one of the following: forming a color filter layer over a substrate having a plurality of photodiodes formed therein; and then forming a photoresist film over the color filter layer; and then performing a first exposure process on the photoresist film; and then performing a second exposure process on the photoresist film after using a performing the first exposure process; and then forming a micro lens by developing the photoresist film after performing the second exposure process.

### DRAWINGS

Example FIGS. 1 to 4 are cross-sectional views showing processes of a method for manufacturing an image sensor in accordance with embodiments.

### DESCRIPTION

Embodiments are not limited to a specific type of image sensor, and may be applied to all image sensors which employ one or more micro lenses.

As shown in FIG. 1, an interlayer dielectric layer 130 is formed on and/or over a substrate 110 including a plurality of photo diodes 120. The interlayer dielectric layer 130 may be formed in a multi-layer structure. The interlayer dielectric layer 130 may be formed after a first interlayer dielectric layer is formed and then a light shielding layer for preventing light from being incident on and/or over regions other than the photodiode region 120 is formed. Thereafter, a protective layer which protects the device from moisture and scratching may further be formed on and/or over the interlayer dielectric layer 130.

Next, dyeable resist is coated on and/or over the interlayer dielectric layer 130 and exposure and development processes are then performed to form R, G and B color filter layers 140 which filter light for each wavelength-range. In order to secure the flatness for forming a lens layer and to control focal length, a planarization layer (PL) 150 may then be formed on and/or over the color filter layer 140. A photoresist film 170 having a predetermined thickness is then formed on and/or over the planarization layer 150. The photoresist film 170 may be a photoresist film for forming one or more micro lenses. With a general technique, a photoresist pattern having a semi-spherical cross-section is not sufficiently obtained by a photo process, and thus, a reflow process is used. However, in accordance with embodiments, a first focusing process and a second focusing process can be performed using a double focusing method. The number of exposure processes is not limited to two but may be performed three or more times. Meaning, the exposure on the photoresist film 170 may be performed a plurality of times from a plurality of different angles.

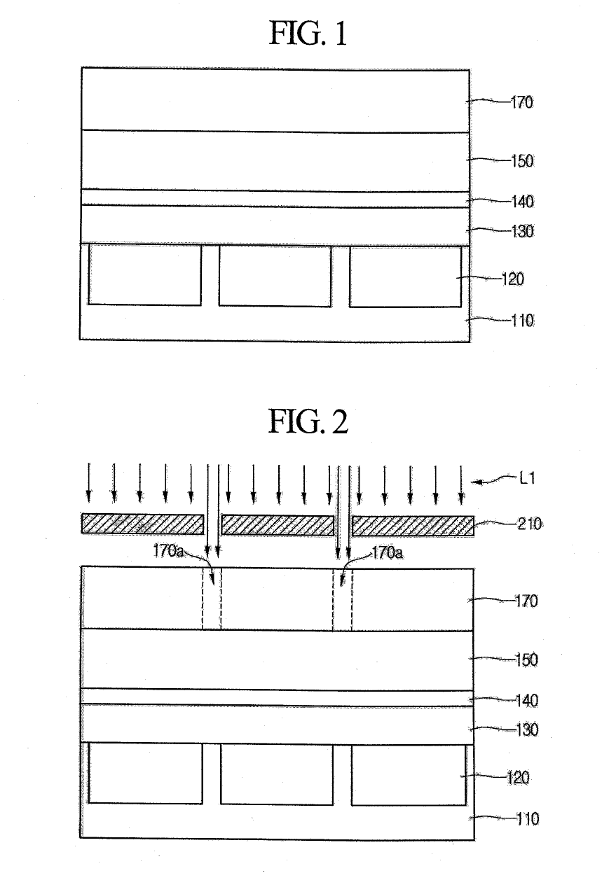

As illustrated in example FIG. 2, for example, an exposure process is performed on the photoresist film 170 in order that the photoresist film 170a in the boundary of the lens is exposed by progressing a best focus through the focusing process using a first reticle 210. A first light L1 is incident perpendicular with respect to the horizontally extending uppermost surface of the photoresist film 170 to expose a portion of the photoresist film 170 corresponding to the boundary (i.e., space between neighboring micro lenses) of the micro lens is exposed. The first focusing process contributes for forming a central part of the micro lens.

As illustrated in example FIG. 3, next, a defocus process is performed through a second focusing process using a second reticle 220 by exposing a best focus. The condition of the defocus process, which is the second focus process, is set to be optimized according to the size and thickness of the edge portion of the micro lens. By performing two separate exposure processes, embodiments solves the difficulties in obtaining optimal shapes of central and edge portions of the micro lens that otherwise cannot be obtained in a single exposure process. Therefore, a reflowing process is not required. For example, the boundary portion 170b of the photoresist film 170 is exposed by a second light L2. Meaning, the peripheral surface of the micro lenses is exposed in the second focusing process. The second light L2 may be tilted at an angle to be incident. The second reticle 220 may use the first reticle as it is or use other reticle.

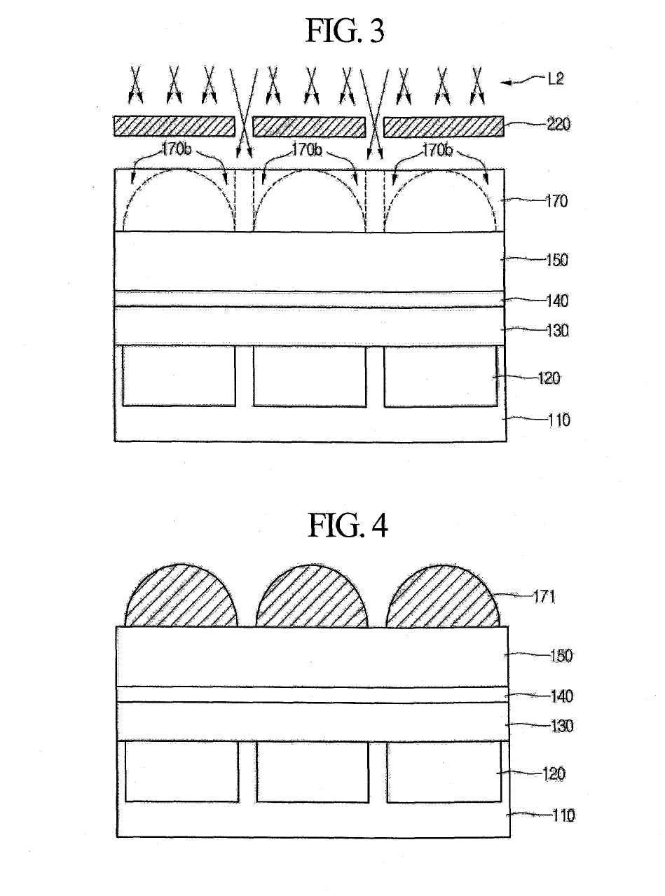

As illustrated in example FIG. 4, the micro lenses 171 are formed through a development process without requiring a reflow process, making it possible to prevent a bridge of the micro lenses and minimize the gap between the micro lenses. Furthermore, since the portion of the photoresist film 170a exposed through the first focusing process shown in example FIG. 2 is developed, the micro lens are defined for each photodiode 120. Since the portion of the photoresist film 170b exposed through the second focusing process shown in example FIG. 3 is developed, the peripheral surface of each micro lens is formed, for example, in a semi-spherical cross-section.

In accordance with embodiments, a method for manufacturing an image sensor can form a micro lens to differ focus in order to adjust the micro lens gap and shape of the micro lens and to perform a double exposure or an exposure a plurality of times without requiring a reflow process. Therefore, the method in accordance with embodiments can simplify the process of forming the micro lens, minimize the micro lens gap while preventing the bridge of the micro lens to increase the quantity of light incident on the photo diode, and thus, maximize image quality.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming an interlayer dielectric layer over a substrate in which a photodiode is formed; and then
forming a photoresist film over the interlayer dielectric layer; and then
exposing the photoresist film a plurality of times from a plurality of different angles; and then
forming a micro lens by developing the exposed photoresist film.

2. The method of claim 1, wherein exposing the photoresist film comprises:
performing a best focus exposure on the photoresist film; and then
performing a defocus exposure on the best focus exposed photoresist film.

3. The method of claim 2, wherein performing the best focus exposure comprises exposing the photoresist film in the spaces between neighboring micro lenses.

4. The method of claim 3, wherein performing the defocus exposure comprises exposing the peripheral surface edge of the photoresist film.

5. The method of claim 2, wherein performing the best focus exposure comprises exposing incident light on the photoresist film at angle perpendicular to the uppermost surface of the photoresist film.

6. The method of claim 2, wherein performing the defocus exposure comprises exposing light on the photoresist film at an angle not perpendicular to the uppermost surface of the photoresist film.

7. The method of claim 2, wherein a reticle used in performing the defocus exposure is the same as a reticle used in performing the best focus exposure.

8. The method of claim 2, wherein a reticle used in performing the defocus exposure is different from a reticle used in performing the best focus exposure.

9. A method comprising:
providing a substrate having a plurality of photodiodes formed therein; and then
forming a dielectric layer over the substrate including the photodiodes; and then
forming a color filter layer over the dielectric layer; and then
forming a planarization layer over the color filter layer; and then
forming a photoresist film over the planarization layer; and then
performing a first focusing process on the photoresist film; and then
performing a second focusing process on the photoresist film after using a performing the first focusing process; and then
forming a micro lens by developing the photoresist film after performing the second focusing process.

10. The method of claim 9, wherein performing the first focusing process comprises using a first reticle to expose light incident at angles perpendicular with respect to the uppermost surface of the photoresist film on a portion of the photoresist film corresponding to the space between neighboring micro lenses.

11. The method of claim 10, wherein performing the second focusing process comprises using the first reticle to expose light incident at angles not perpendicular with respect to the uppermost surface of the photoresist film on peripheral edge portions of the photoresist film.

12. The method of claim 9, wherein performing the second focusing process comprises using a reticle to expose light incident at angles not perpendicular with respect to the uppermost surface of the photoresist film on peripheral edge portions of the photoresist film.

13. The method of claim 9, wherein performing the first focusing process comprises performing a best focus exposure on the photoresist film.

14. The method of claim 9, wherein performing the second focusing process comprises performing a defocus exposure on the photoresist film.

15. A method comprising:
forming a color filter layer over a substrate having a plurality of photodiodes formed therein; and then
forming a photoresist film over the color filter layer; and then sequentially performing first and second exposure processes on the photoresist film; and then
forming a micro lens by developing the photoresist film after performing the second exposure process.

16. The method of claim 15, wherein performing the first exposure process comprises using a first reticle to expose light incident at angles perpendicular with respect to the uppermost surface of the photoresist film on a portion of the photoresist film corresponding to the space between neighboring micro lenses.

17. The method of claim 16, wherein performing the second exposure process comprises using a second reticle to expose light incident at angles not perpendicular with respect to the uppermost surface of the photoresist film on peripheral edge portions of the photoresist film.

18. The method of claim 17, wherein the second reticle is different than the first reticle.

19. The method of claim 15, wherein performing the second exposure process comprises using a reticle to expose light incident at angles not perpendicular with respect to the uppermost surface of the photoresist film on peripheral edge portions of the photoresist film.

20. The method of claim 15, wherein the first exposure process comprises performing a best focus exposure process on the photoresist film and the second exposure process comprises performing a defocus exposure on the photoresist film.
